(19) United States
(12) Patent Application Publication
(10) Pub. No.: US 2009/0016021 A1
(43) Pub. Date: Jan. 15, 2009

(54) Cooling structure for high voltage electrical parts of hybrid electric vehicle

(75) Inventors: Hae Kyu Kim, Gyeonggi-do (KR); Dal Kim, Gyeonggi-do (KR); Nam Seob Park, Seoul (KR); Yoshiro Shimoyama, Chiba (JP)

Correspondence Address: EDWARDS ANGELL PALMER & DODGE LLP, P.O. BOX 55874, BOSTON, MA, 02205, US

(73) Assignees: Hyundai Motor Company, Seoul (KR); Kia Motors Corporation, Seoul (KR)

(21) Appl. No.: 11/983,174

(22) Filed: Nov. 6, 2007

(30) Foreign Application Priority Data
Jul. 13, 2007 (KR) 10-2007-0070674

(51) Int. Cl. H05K 7/20

(52) U.S. Cl. 361/697; 363/141

(57) ABSTRACT

The present invention provides a cooling structure for high voltage electrical parts of an HEV, in which a plurality of high voltage electrical parts including a DC-DC converter, an inverter, and an air conditioner inverter are arranged on a cross section of a cooling air passage in a direction horizontal to the flow of cooling air, a cooling blower for cooling the high voltage electrical parts is mounted on one side of an electrical part package in the opposite direction, and; and a duct is integrally formed on an upper portion of the blower so that the cooling air passing through the electrical part package is discharged therethrough, thereby being able to supply the cooling air at the same temperature to the plurality of high voltage electrical parts and mount the electrical part package in a relatively small space.

### CROSS-REFERENCE TO RELATED APPLICATION

This application claims under 35 U.S.C. §119(a) on Korean Patent Application No. 10-2007-0070674, filed on Jul. 13, 2007, the entire contents of which are incorporated herein by reference.

### BACKGROUND

(a) Technical Field

The present invention relates to a cooling structure for high voltage electrical parts of a hybrid electric vehicle (HEV). More particularly, the present invention relates to a cooling structure for high voltage electrical parts of an HEV, in which a plurality of high voltage electrical parts cooled by air are arranged on a cross section of a cooling air passage in a direction horizontal to the flow of cooling air, and a cooling blower for cooling the high voltage electrical parts is mounted on one side of an electrical part package in the opposite direction, thereby integrating the high voltage electrical parts with the cooling blower.

(b) Background Art

In general, electrical systems of a vehicle include engine electrical systems, such as a starter system, an ignition system and a charging system, and lighting systems. However, as vehicles are more electronically controlled than before, most of their systems including a chassis electrical system have been computerized.

Various electrical parts, such as a lamp, an audio system, a heater, an air conditioner, etc., equipped in a vehicle receive power from a battery when the vehicle is stopped and from a generator when the vehicle is driven. Generally, a generation capacity of a 14V power system is used as a power voltage.

Recently, with the development of information technologies, various new technologies such as a motor-driven power steering, Internet, and the like have been applied to a vehicle in order to increase the convenience of using the vehicle. Moreover, it is expected that the development of new technologies to make the most of the existing vehicle systems will continue to progress.

A low voltage DC-DC converter for supplying 12V electrical loads is installed in a hybrid electric vehicle (HEV) irrespective of soft or hard type.

In general, a DC-DC converter used as an alternator of a vehicle converts high voltage power into low voltage power to supply energy to the 12V electrical loads and charge a 12V battery.

Besides the DC-DC converter, the high voltage electrical parts include an inverter and an air conditioner inverter which convert DC voltage into AC voltage and supply the AC voltage to motors.

In connection with the cooling structure for the high voltage electrical parts, Japanese Patent Application Laid-Open Publication No. 1995-067213 discloses an electric automobile in which a cooling block and a cooling blower are disposed between a controller for a DC/DC converter and a controller for an air conditioner inverter.

Japanese Patent Application Laid-Open Publication No. 2001-018664 discloses a cooling structure in which a fan and an inlet port are provided to an air cooler, and the inlet port is connected to a PDU and an air cooler of a downverter through a pipe.

Japanese Patent Application Laid-Open Publication No. 2001-020737 discloses a similar cooling structure for high voltage electrical parts.

FIGS. 1 and 2 are diagrams illustrating the cooling structure disclosed in Japanese Patent Laid-Open No. 2001-020737, and FIG. 3 is a cross-sectional view of the cooling structure of FIG. 1 taken along line A-A.

As shown in FIGS. 1 to 3, the prior art cooling structure for high voltage electrical parts is provided with a cooling hole acting as a passage of cooling air formed on the wall of a case of a heat sink 4 to cool high voltage electrical parts including a power unit 1 and a DC-DC converter 2. It is also provided with the heat sink 4 disposed between the high voltage electrical parts to blow cooling air to the high voltage electrical parts.

In FIGS. 1 to 3, reference numeral 3 denotes a cooling device, 5 denotes an air inlet, 6 denotes an air outlet, 7a denotes a first heat sink, 7b denotes a second heat sink, and 8 denotes a fan.

However, in the above structure, if the number of high voltage electrical parts is increased, the electrical parts should be disposed on the upstream or the downstream of a cooling air passage and the length of the cooling air passage between the upstream side and the downstream side will thus be required to increase, causing the cooling performance to be lowered in the downstream side by a difference in temperature of the cooling air.

The information disclosed in this Background section is only for enhancement of understanding of the background of the invention and should not be taken as an acknowledgement or any form of suggestion that this information forms the prior art that is already known to a person skilled in the art.

### SUMMARY OF THE INVENTION

The present invention has been made in an effort to solve the above problems, and an object of the present invention is to provide a cooling structure of high voltage electrical parts for a hybrid electric vehicle (HEV) that can improve cooling performance and space utilization.

In one aspect, the present invention provides a cooling structure for high voltage electrical parts of a hybrid electric vehicle in which a plurality of high voltage electrical parts are cooled by air, the cooling structure comprising: an electrical part package in which the plurality of high voltage electrical parts and heat sinks are arranged in a direction horizontal to the flow of cooling air; a blower closely attached to one side of the electrical part package to cool the high voltage electrical parts; and a duct integrally formed on an upper portion of the blower so that the cooling air passing through the electrical part package is discharged therethrough.

In a preferred embodiment, the plurality of high voltage electrical parts includes a DC-DC converter, an inverter, and an air conditioner inverter.

Preferably, a bracket is provided on both sides of the electrical part package to form a cooling air passage.

More preferably, the bracket is connected to the electrical part package by a bolt and a nut.

Suitably, the bracket is connected to the blower in a mounting structure.

### BRIEF DESCRIPTION OF THE DRAWINGS

FIGS. 1 and 2 are diagrams illustrating a conventional cooling structure for high voltage electrical parts;

FIG. 3 is a cross-sectional view of the cooling structure of FIG. 1 taken along line A-A;

FIG. 4 is a perspective view of a cooling structure for high voltage electrical parts of a hybrid electric vehicle (HEV) in accordance with an exemplary embodiment of the present invention;

FIG. 5 is a front view of the cooling structure for high voltage electrical parts of an HEV in accordance with the exemplary embodiment of the present invention;

FIG. 6 is a side view of the cooling structure for high voltage electrical parts of an HEV in accordance with the exemplary embodiment of the present invention; and

FIG. 7 is a rear perspective view of the cooling structure for high voltage electrical parts of an HEV in accordance with the exemplary embodiment of the present invention.

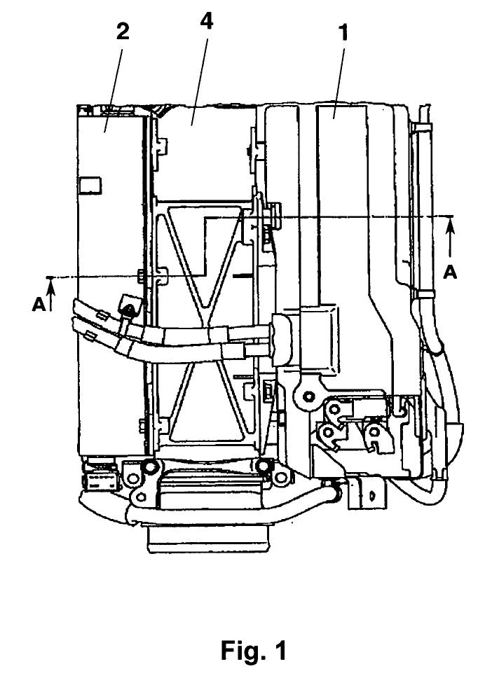

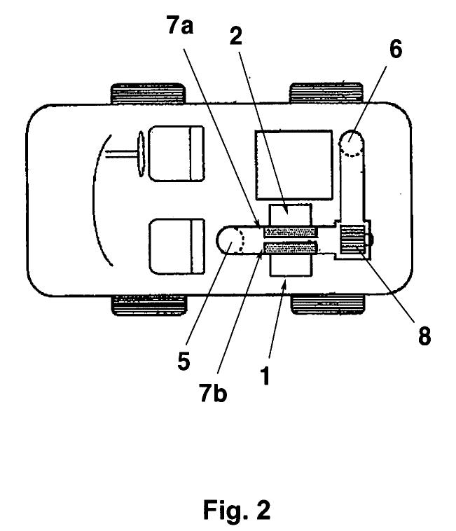

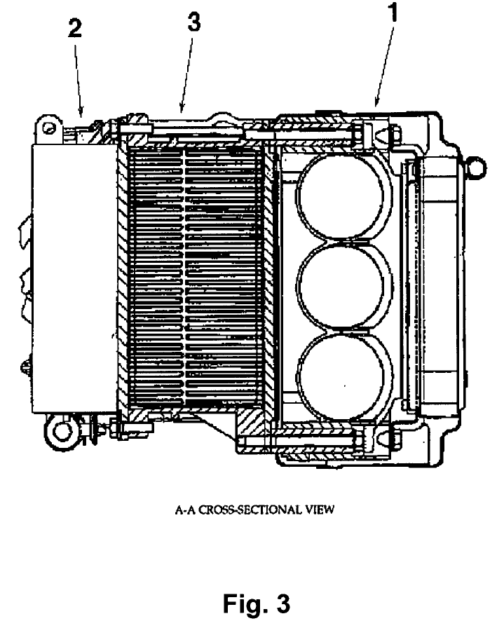

Reference numerals set forth in the Drawings includes reference to the following elements as further discussed below:
200: electrical part package
210: DC-DC converter
220: inverter
230: air conditioner inverter
250 and 255: heat sinks
260: cooling air
270: blower
280: duct
290 and 300: brackets
360: mounting structure

### DETAILED DESCRIPTION

Reference will now be made in detail to the preferred embodiment of the present invention, examples of which are illustrated in the drawings attached hereinafter, wherein like reference numerals refer to like elements throughout. The embodiments are described below so as to explain the present invention by referring to the figures.

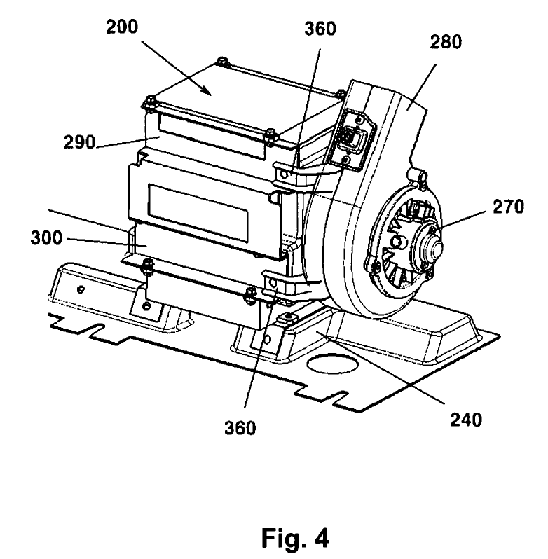

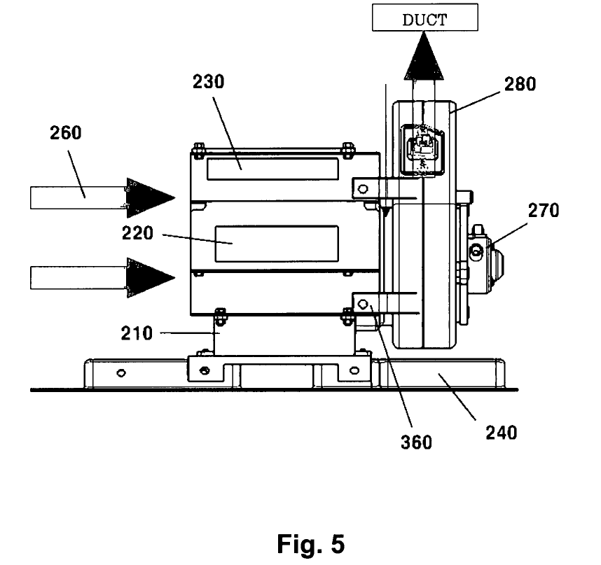

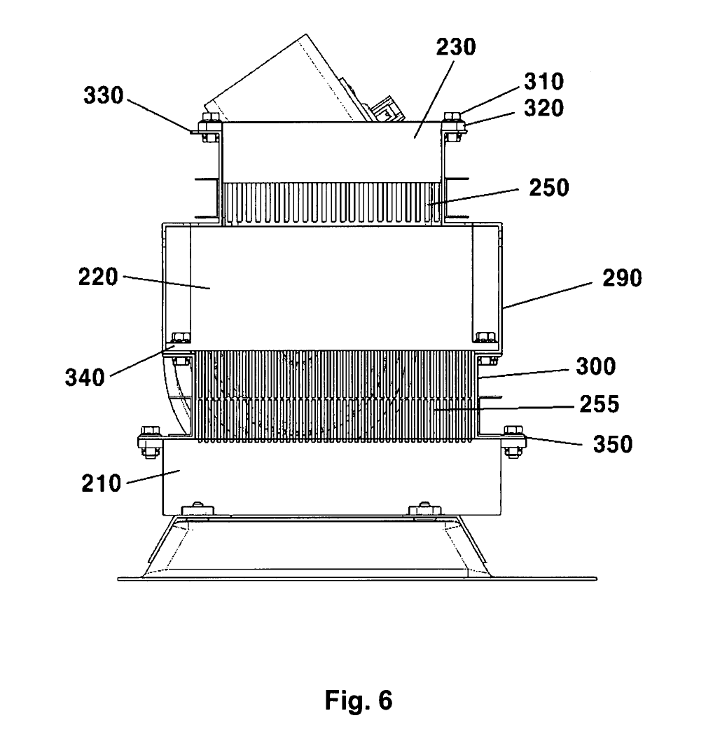

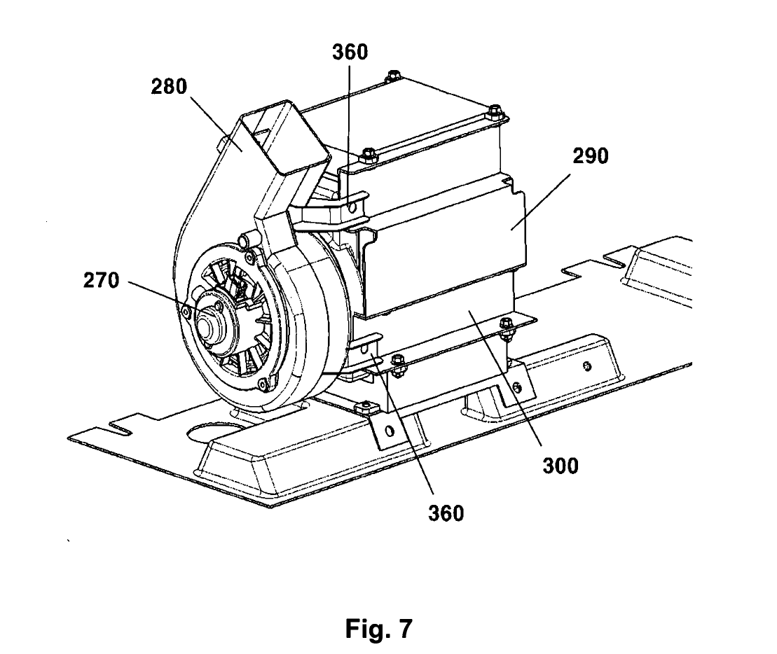

FIG. 4 is a perspective view of a cooling structure for high voltage electrical parts of a hybrid electric vehicle (HEV) in accordance with an exemplary embodiment of the present invention, FIG. 5 is a front view of the cooling structure for high voltage electrical parts of an HEV in accordance with the exemplary embodiment of the present invention, FIG. 6 is a side view of the cooling structure for high voltage electrical parts of an HEV in accordance with the exemplary embodiment of the present invention, and FIG. 7 is a rear perspective view of the cooling structure for high voltage electrical parts of an HEV in accordance with the exemplary embodiment of the present invention.

As shown in FIG. 6, the cooling structure for high voltage electrical parts in accordance with the exemplary embodiment of the present invention, heat sinks 250 and 255 are provided between a plurality of high voltage electrical parts in order to cool the plurality of high voltage electrical parts and, as shown in FIG. 5, the respective electrical parts and the heat sinks 250 and 255 are arranged in a direction horizontal to the flow of cooling air 260.

Like this, an electrical part package 200 comprises the plurality of high voltage electrical parts and the heat sinks 250 and 255 arranged in a direction horizontal to the flow of the cooling air 260. This structure has no limitation on the number of the high voltage electrical parts that can be provided therein. For example, with this structure, one, two, three or more of high voltage electrical parts can be provided.

Here, the high voltage electrical parts include a DC-DC converter 210, an inverter 220, and an air conditioner inverter 230.

In particular, it is preferable that the DC-DC converter 210, the inverter 220, and the air conditioner inverter 230 are arranged in the sequential order horizontally from a base 240, formed on the lowermost surface, and the heat sinks 250 and 255 are provided between the respective electrical parts to cool them.

As shown in FIG. 6, it is preferable that the cross sections of the heat sinks 250 and 255 have projections in the form of comb teeth in order to enhance the heat radiation.

As above, the plurality of high voltage electrical parts are horizontally arranged on a cross section of a cooling air passage with the heat sinks 250 and 255 disposed therebetween such that the cooling air 260 at the same temperature can be supplied to the plurality of high voltage electrical parts.

A blower 270 is attached to one side of the electrical part package 200 to cool the high voltage electrical parts.

In this case, the blower 270 may comprise a propeller for blowing wind by rotation, a motor for rotating the propeller, and a power unit for supplying power to the motor.

Moreover, a duct 280 is integrally formed on an upper portion of the blower 270 to allow the cooling air 260 passing through the electrical part package 200 to be discharged therethrough.

Brackets 290 and 300 are designed according to the shape of the heat sinks 250 and 255 and mounted on both sides of the electrical part package 200. Accordingly, a cooling air passage is formed by such brackets 290 and 300 and thereby the cooling air 260 passes through the heat sinks 250 and 255.

The brackets 290 and 300 are connected to the respective electrical parts and the heat sinks 250 and 255 by means of a bolt 310 and nut 320 and may be provided in a plural number thereof.

In particular, an upper connection portion of the first bracket 290 is closely attached to both sides of the air conditioner inverter 230 and the first heat sink 250, and first projections 330 are formed on the top of the upper connection portion, to which the bolt 310 and the nut 320 are connected, such that the air conditioner 230 and the first heat sink 250 are fixed and integrated with each other.

Moreover, a lower connection portion of the first bracket 290 is connected to lower projections 340 of the inverter 220 and the second bracket 300 by means of the bolt 310 and the nut 320 such that the inverter 220 and the second heat sink 255 are fixed and integrated with each other.

The second bracket 300 connected to the first bracket 290 as described above is closely attached to the second heat sink 255 and connected to a second projection 350 formed on the bottom of the inverter 220 by means of the bolt 310 and the nut 320, such that the DC-DC converter 210 and the second heat sink 255 are fixed and integrated with each other.

Accordingly, since the plurality of brackets 290 and 300 are closely attached to the high voltage electrical parts to prevent the cooling air 260 from leaking, it is possible to improve the cooling performance and achieve a compact package structure.

The structure of the brackets 290 and 300 are not limited to the above-described structure, but may be modified according to the shape and structure of the high voltage electrical parts and the heat sinks 250 and 255.

As shown in FIG. 4, the bracket may be connected to the blower 270 in a mounting structure 360 such that the electrical part package 200 and the blower 270 are integrated with each other, thus improving the assembling efficiency and minimizing the loss of the cooling air 260.

Here, it is preferable that the mounting structure 360 is provided on the first and second brackets 290 and 300, respectively, to firmly connect the blower 270.

Moreover, it is preferable that the mounting structure 360 is further provided on the rear surface of the first and second brackets 290 and 300, respectively, as shown in the rear perspective view of FIG. 7.

With the blower 270 connected to the brackets 290 and 300 by the mounting structure 360, it is possible to prevent deterioration of workability and generation of vibration and noise caused when the blower 270 is mounted on the electrical part package 200.

As described above, the cooling structure for high voltage electrical parts of an HEV in accordance with the present invention provides advantages including the following:

1) Since the high voltage electrical parts are arranged in a direction horizontal to the flow of cooling air and cooled by the cooling air at the same temperature, the cooling performance is improved;

2) With the bracket designed according to the shape of the heat sink, the cooling air passage is formed such that the cooling air can pass through the heat sink uniformly;

3) Since the blower and the duct are closely attached to the high voltage electrical parts, it is possible to improve the assembling efficiency and minimize the loss of the cooling air; and

4) Since the blower is connected to the brackets by the mounting structure, it is possible to prevent deterioration of workability and generation of vibration and noise caused when the blower is mounted on the electrical part package.

The invention has been described in detail with reference to preferred embodiments thereof. However, it will be appreciated by those skilled in the art that changes may be made in these embodiments without departing from the principles and spirit of the invention, the scope of which is defined in the appended claims and their equivalents.

What is claimed is:

1. A cooling structure for high voltage electrical parts of a hybrid electric vehicle in which a plurality of high voltage electrical parts are cooled by air, the cooling structure comprising:
an electrical part package in which the plurality of high voltage electrical parts and heat sinks are arranged in a direction horizontal to the flow of cooling air;
a blower closely attached to one side of the electrical part package to cool the high voltage electrical parts; and
a duct integrally formed on an upper portion of the blower so that the cooling air passing through the electrical part package is discharged therethrough.

2. The cooling structure of claim 1, wherein the plurality of high voltage electrical parts includes a DC-DC converter, an inverter, and an air conditioner inverter.

3. The cooling structure of claim 1, wherein a bracket is provided on both sides of the electrical part package to form a cooling air passage.

4. The cooling structure of claim 3, wherein the bracket is connected to the electrical part package by a bolt and a nut.

5. The cooling structure of claim 3, wherein the bracket is connected to the blower in a mounting structure.
